(19) United States
(12) Patent Application Publication
(10) Pub. No.: US 2011/0024171 A1
(43) Pub. Date: Feb. 3, 2011

(54) MULTILAYER LAMINATED CIRCUIT

(75) Inventors: Mikio NAKAMURA, Tokyo (JP); Hiroshi SUZUSHIMA, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/846,302

(22) Filed: Jul. 29, 2010

(30) Foreign Application Priority Data
Jul. 31, 2009 (JP) 2009-180038

(51) Int. Cl. H05K 1/00

(52) U.S. Cl. 174/258

(57) ABSTRACT

A multilayer laminated circuit includes ceramic layers sandwiched between all adjacent layers of a plurality of passive-element conductor layers and a plurality of wiring conductor layers. At least one of the passive-element conductor layers and the wiring conductor layers is connected to an electrode via a via that pierces through the ceramic layers from a principal-surface top side of the multilayer laminated circuit. External electrodes including an electrode, which is to be connected to the via on the principal-surface top side to make an external connection, are formed on the principal-surface top side. An external wiring conductor that connects at least a pair of the external electrodes is formed on the principal-surface top side.

### CROSS-REFERENCE TO RELATED APPLICATIONS

This application is based upon and claims the benefit of priority from Japanese Patent Application No. 2009-180038, filed on Jul. 31, 2009, the entire contents of which are incorporated herein by reference.

### BACKGROUND OF THE INVENTION

1. Field of the Invention

The present invention relates to a multilayer laminated circuit that includes ceramic layers sandwiched between all adjacent layers of a plurality of passive-element conductor layers and a plurality of wiring conductor layers.

2. Description of the Related Art

Conventionally, a circuit on an end portion of an endoscope has been downsized by using a multilayer integrated circuit to further decrease a diameter of the endoscope and shorten the length of a hard portion.

As the multilayer integrated circuit, as disclosed in Japanese Patent No. 2627625, a compact laminated integrated circuit including a capacitor for example is constructed by integrally stacking a laminated ceramic capacitor substrate on a base multilayer wiring substrate and forming an external electrode on the side surfaces of the substrates.

### SUMMARY OF THE INVENTION

A multilayer laminated circuit according to an aspect of the present invention includes a plurality of passive-element conductor layers; a plurality of wiring conductor layers; a plurality of ceramic layers between all adjacent layers of the passive-element conductor layers and the wiring conductor layers; at least two first external connection electrodes formed on a principal surface of the multilayer laminated circuit; a first external wiring conductor that is formed on the principal surface and that connects at least a pair of the first external connection electrodes; and a first via that pierces through at least one of the ceramics layers and that electrically connects at least one of the passive-element conductor layers and wiring conductor layers to at least one of the first external connection electrodes.

The above and other features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view of a structure of a multilayer laminated circuit according to a first embodiment of the present invention;

FIG. 2A is a perspective view of the multilayer laminated circuit;

FIG. 2B is a diagram illustrating an integrated circuit module made up by connecting the multilayer laminated circuit to the external connection device;

FIG. 3 is a cross-sectional view of a structure of the made-up integrated circuit module;

FIG. 4 is a cross-sectional view of a structure of a multilayer laminated circuit according to a second embodiment of the present invention;

FIG. 5 is a cross-sectional view of a structure of an integrated circuit module made up by connecting the multilayer laminated circuit to an external connection device; and

FIG. 6 is a perspective view of the structure of the integrated circuit module made up by connecting the multilayer laminated circuit to the external connection device.

### DETAILED DESCRIPTION OF THE PREFERRED EMBODIMENTS

Exemplary embodiments of the present invention are explained in detail below with reference to the accompanying drawings. The present invention is not limited by the following embodiments. In the following explanation, each drawing only schematically represents the shape, size, and positional relationship such that the contents of the present invention are understood; therefore, the present invention is not limited by the shape, size, and positional relationship that are exemplified in the drawings.

### First Embodiment

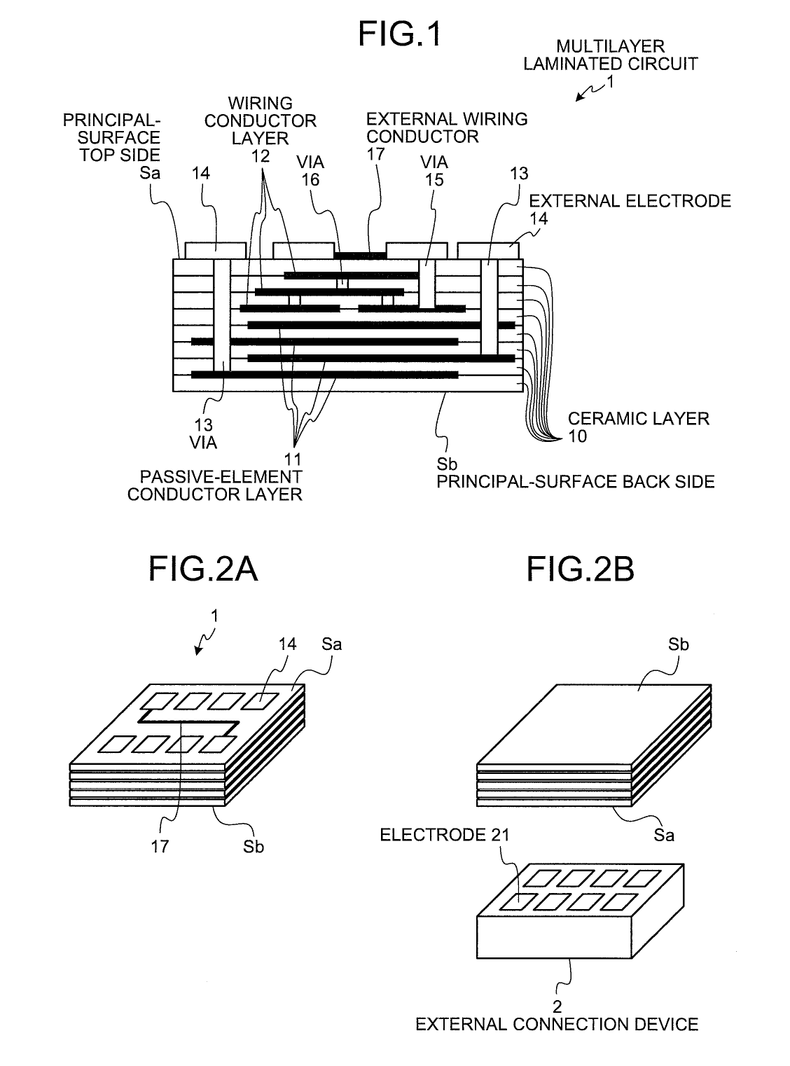

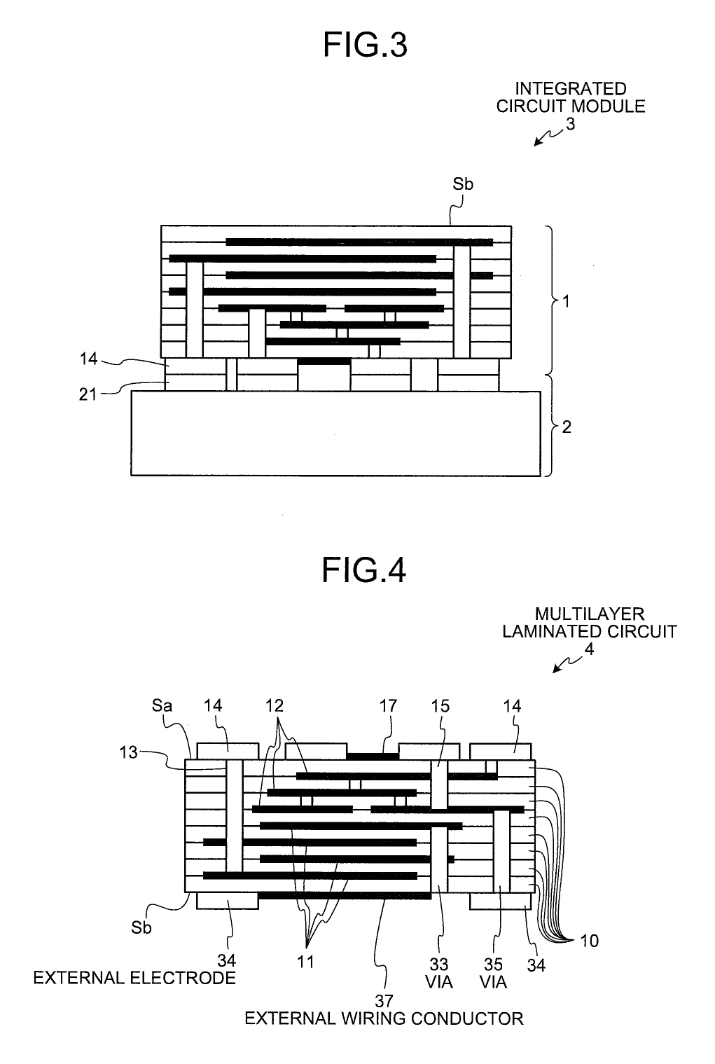

FIG. 1 is a cross-sectional view of a structure of a multilayer laminated circuit according to a first embodiment of the present invention. FIG. 2A is a perspective view of the multilayer laminated circuit. FIG. 2B is a diagram illustrating an integrated circuit module made up by connecting the multilayer laminated circuit to the external connection device. FIG. 3 is a cross-sectional view of a structure of the made-up integrated circuit module. As illustrated in FIG. 1, a multilayer laminated circuit 1 is constructed by forming conductor layers between each of laminated ceramic layers 10 such that passive-element conductor layers 11 between the bottom ceramic layers 10 form a passive element such as a capacitor or a resistor and wiring conductor layers 12 between the top ceramic layers 10 form wiring. In the multilayer laminated circuit 1, an example structure is illustrated in which a laminated capacitor is formed as part of the passive element.

A plurality of external electrodes 14 (external connection electrodes) for making an electrical connection to an external apparatus is formed on a principal-surface top side Sa being a top surface of the topmost ceramic layer 10. The external electrodes 14 and the passive-element conductor layers 11 are connected to each other via a via 13 that pierces through the ceramic layers 10. The via 13 is a blind via of which one end is connected to the principal-surface top side Sa, and which connects the external electrodes 14 that are exposed outside to the internal passive-element conductor layers 11. A conductor layer is formed on the inner wall or over the whole interior portion of a hole of the via 13, so that the external electrodes 14 and the passive-element conductor layers 11 are electrically connected to each other. It is possible to insert a lead wire such as a copper wire inside the hole.

The external electrodes 14 formed on the principal-surface top side Sa are connected to the internal wiring conductor layers 12 via a via 15. The internal wiring conductor layers 12 are connected to each other via buried vias 16, so that a complex and three-dimensional wiring is formed. The wiring is not limited to the internal wiring, and it is possible to form an external wiring conductor 17 between the external electrodes 14 on the principal-surface top side Sa as illustrated in FIG. 2A.

The passive-element conductor layers 11 and the wiring conductor layers 12 are formed on the top surface or the back surface of each ceramic layer 10 by patterning, and the patterned ceramic layers 10 are joined together. Subsequently, the buried vias 16 are formed at a step of stacking the ceramic layers 10, and then after the ceramic layers 10 are stacked, the vias 13 and 15 that communicate with the principal-surface top side Sa are formed. Conductor layers are formed on the inner wall surfaces of the vias 16, 13, and 15 as described above. Subsequently, the external electrodes 14 are formed by a process such as plating, inkjet patterning, or the like. Furthermore, the external wiring conductor 17 is formed as described above. Thus, the multilayer laminated circuit 1 as described above is formed.

Subsequently, as illustrated in FIG. 2B, the multilayer laminated circuit 1 is turned over to turn the principal-surface top side Sa downward, and the principal-surface top side Sa and a surface having electrodes 21 of an external connection device 2 such as an active device prepared in advance are connected to each other while facing each other. As a result, an integrated circuit module 3 as illustrated in FIG. 3 is formed. Each external electrode 14 and each electrode 21 are formed on the principal-surface top side Sa and the surface on the electrodes 21 side of the external connection device 2, respectively, such that they coincide with each other in the connected state. Each external electrode 14 and each electrode 21 may be connected to each other by using a solder bump. It is also possible to insert insulating adhesive between each external electrode 14 and each electrode 21 to increase the connection strength.

In the multilayer laminated circuit 1, because the external electrodes are formed on the large principal-surface top side Sa, and also because the internal wiring is formed, design possibilities can be enhanced, so that it is possible to form a circuit which can be equipped with a number of functions. Furthermore, in the integrated circuit module 3, because the external electrodes 14 are not formed on the side surfaces and a principal-surface back side Sb of the multilayer laminated circuit 1, a portion that is electrically connected to the outside is reduced, so that it is possible to form a module resistant to external stress, contact, or the like.

### Second Embodiment

In the first embodiment described above, the external electrodes 14 are formed only on the principal-surface top side Sa of the multilayer laminated circuit 1. However, in a second embodiment, external electrodes are formed on both the principal-surface top side Sa and the principal-surface back side Sb.

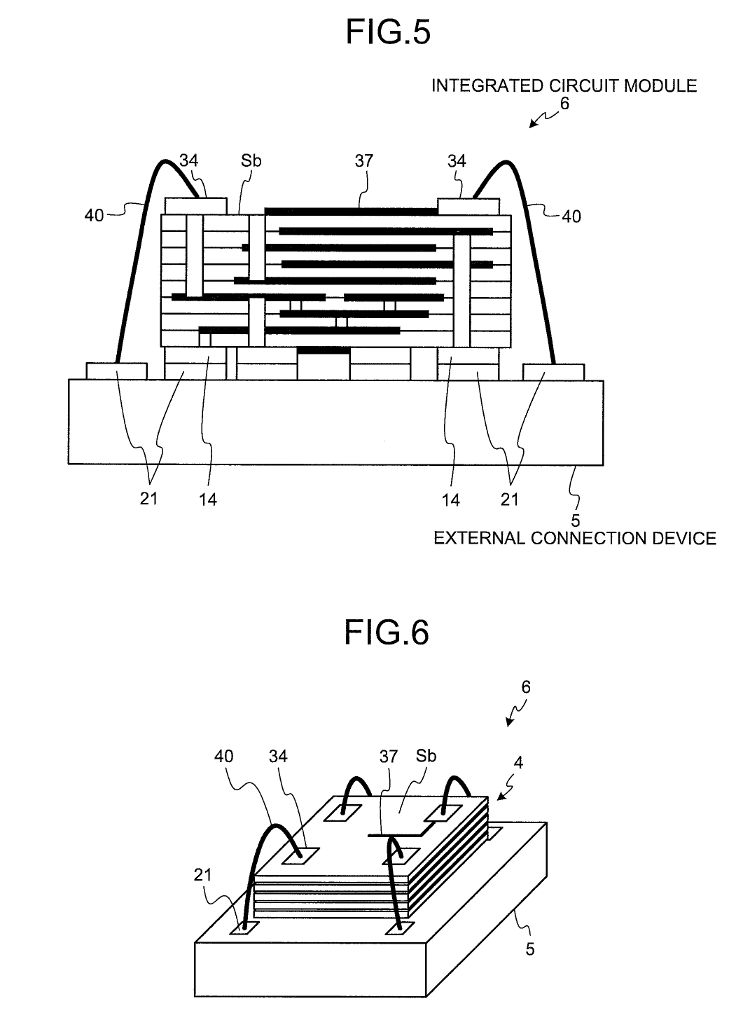

FIG. 4 is a cross-sectional view of a structure of a multilayer laminated circuit according to a second embodiment of the present invention. FIG. 5 is a cross-sectional view of a structure of an integrated circuit module made up by connecting the multilayer laminated circuit to an external connection device. FIG. 6 is a perspective view of the structure of the integrated circuit module made up by connecting the multilayer laminated circuit to the external connection device. As illustrated in FIG. 4, a multilayer laminated circuit 4 includes external electrodes 34 formed on the principal-surface back side Sb similarly to the external electrodes 14. The multilayer laminated circuit 4 also includes vias 33, 35, and the like in addition to the vias 13 and 15 to connect the internally-formed passive-element conductor layers 11 and the internally-formed wiring conductor layers 12 to the principal-surface back side Sb. Furthermore, similarly to the external wiring conductor 17, the multilayer laminated circuit 4 includes an external wiring conductor 37 formed on the principal-surface back side Sb.

As illustrated in FIGS. 5 and 6, similarly to the multilayer laminated circuit 1, the multilayer laminated circuit 4 is turned over to turn the principal-surface top side Sa toward an external connection device 5, and each external electrode 14 and each electrode 21 are electrically connected to and combined with each other. The external electrodes 34 on the principal-surface back side Sb and the electrodes 21 on the external connection device 5 are wire bonded by wires 40, so that they are electrically connected to each other. Thus, an integrated circuit module 6 is formed. The wires 40 are connected to the electrodes 21 at positions that are on the external connection device 5 and are not covered by the principal-surface top side Sa of the multilayer laminated circuit 4.

While the single multilayer laminated circuit 4 is explained as an example in the second embodiment described above, the present invention is not limited to this example. For example, it is possible to form a multistage multilayer integrated circuit by connecting the principal-surface top side Sa and the principal-surface back side Sb to each other. Furthermore, while the wires 40 are used to make a connection to the principal-surface back side Sb in the second embodiment described above, the present invention is not limited to this configuration. For example, it is possible to form wiring between the external electrodes 34 on the principal-surface back side Sb and the electrodes 21 by inkjet printing or the like along the side surfaces of the multilayer laminated circuit 4.

In the multilayer laminated circuit 4, because the external electrodes are further formed on the principal-surface back side Sb, design possibilities can further be enhanced, so that it is possible to form a circuit which can be equipped with even more number of functions. In particular, it is possible to selectively make an electrical connection between the principal-surface back side Sb and the external connection device 5.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multilayer laminated circuit comprising:
a plurality of passive-element conductor layers;
a plurality of wiring conductor layers;
a plurality of ceramic layers between all adjacent layers of the passive-element conductor layers and the wiring conductor layers;
at least two first external connection electrodes formed on a principal surface of the multilayer laminated circuit;
a first external wiring conductor that is formed on the principal surface and that connects at least a pair of the first external connection electrodes; and
a first via that pierces through at least one of the ceramics layers and that electrically connects at least one of the passive-element conductor layers and wiring conductor layers to at least one of the first external connection electrodes.

2. The multilayer laminated circuit according to claim 1, further comprising:
at least two second external connection electrodes formed on a back surface of the multilayer laminated circuit, the back surface being located on an opposite side of the principal surface;
a second external wiring conductor that is formed on the back surface and that connects at least a pair of the second external connection electrodes; and
a second via that pierces through at least one of the ceramic layers and that electrically connects at least one of the passive-element conductor layers and wiring conductor layers to the second external connection electrodes.

3. The multilayer laminated circuit according to claim 1, wherein at least one of the first external connection electrodes is connected to other member by an opposing electrode.

4. The multilayer laminated circuit according to claim 2, wherein at least one of the second external connection electrodes is connected to other member by an opposing electrode.
